(19) United States
(12) Patent Application Publication
(10) Pub. No.: US 2012/0018739 A1
(43) Pub. Date: Jan. 26, 2012

(54) BODY CONTACT DEVICE STRUCTURE AND METHOD OF MANUFACTURE

(75) Inventors: Qingqing Liang, Bejing (CN); Huicai Zhong, Bejing (CN)

(73) Assignee: INSTITUTE OF MICROELECTRONICS-CHINESE ACADEMY OF SCIENCES, BEIJING (CN)

(21) Appl. No.: 13/058,996

(22) PCT Filed: Sep. 25, 2010
(86) PCT No.: PCT/CN10/77274

§ 371 Date: Feb. 14, 2011

(30) Foreign Application Priority Data
Feb. 9, 2010 (CN) 201010110029.7

(51) Int. Cl. H01L 29/78; H01L 29/12; H01L 29/16; H01L 21/336

(52) U.S. Cl. 257/77; 438/299; 438/105; 257/192; 257/E21.409; 257/E29.255; 257/E29.068; 257/E29.082

(57) ABSTRACT

The present invention provides a body contact device structure and a method for manufacturing the same. According to the present invention, an opening is formed by removing one end of a dummy gate stack after forming the dummy gate stack, wherein a residual portion of the dummy gate stack is a body stack comprising a body pile-up layer that directly contacts a substrate. Next, a replacement gate stack is formed in the opening, and then a body contact is formed on the body pile-up layer in the body stack. The body contact device structure formed by the method of the present invention effectively reduces the parasitic effects and the device area, and improves the performance of the device structure.

### FIELD OF THE INVENTION

The present invention generally relates to semiconductor devices and methods for manufacturing the same, and particularly, to a body contact device structure based on gate replacement process and a method of manufacture.

### BACKGROUND OF THE INVENTION

For an MOSFET device, body contact is a very important feature that influences to electrical properties thereof. Firstly, it can reduce uncertainty of the switching speed caused by floating body effect. Secondly, it makes it convenient to connect a circuit design body such as a mixer and a Voltage Controlled Oscillator (VCO) from the outside. Currently, body contact structures commonly adopted in the Silicon-On-Insulator (SOI) technology are mainly T-type and H-type gate structures. However, both of the two structures need a body contact area (701) forming an active region and a body contact (702) on the body contact area, and also require a barrier (703) to isolate the body contact area (701) from a source/drain region (704). The T-type gate structure illustrated in FIG. 7 is taken as an example. Such structure increases device area and causes unnecessary parasitic effects such as parasitic gate-body capacitor and parasitic body contact resistor. As illustrated in FIG. 8, the parasitic gate-body capacitor (720) is a parasitic capacitor between the barrier (703) and an intrinsic body (700), and the parasitic body contact resistor (730) is a parasitic resistor between the body contact (702) and the intrinsic body (700). These parasitic effects degrade device performance. In addition, it is difficult to perform intrinsic electrical tests of an SOI short-channel device due to these parasitic effects.

Therefore, it is necessary to provide a body contact device structure capable of effectively reducing or eliminating the parasitic effects.

### SUMMARY OF THE INVENTION

The present invention provides a method for manufacturing a body contact device structure, comprising: providing a semiconductor substrate with an isolation region therein; forming a dummy gate stack on the semiconductor substrate and the isolation region, forming spacers on sidewalls of the dummy gate stack, forming a source region and a drain region in the semiconductor substrate, and forming an insulation dielectric layer to cover the source region, the drain region and the isolation region; removing a portion of the dummy gate stack at one end to form an opening, with the underlying substrate and the isolation region being exposed, wherein a residual portion of the dummy gate stack is a body stack comprising a body pile-up layer that directly contacts the substrate; forming a replacement gate stack, comprising a gate dielectric layer and a gate electrode, in the opening; and forming source/drain contacts on the source region and the drain region, forming a body contact on the body pile-up layer of the body stack, and forming a gate contact on the gate electrode of the replacement gate stack, in which, the body pile-up layer is formed with a material of semiconductor or semiconductor compound different from that of the substrate.

The present invention also provides a body contact device structure, comprising: a semiconductor substrate with an isolation region therein; a source region and a drain region formed on the semiconductor substrate; a body stack and a replacement gate stack formed on the semiconductor substrate and the isolation region between the source region and the drain region wherein the body stack comprises a body pile-up layer, and the replacement gate stack comprises a gate dielectric layer and a gate electrode; spacers formed on sidewalls of the body stack and the replacement gate stack; and source/drain contacts formed on the source region and the drain region, a body contact on the body pile-up layer, and a gate contact on the gate electrode. In which, the body pile-up layer is formed of a material of semiconductor or semiconductor compound different from the substrate.

The body contact device structure formed by the method of the present invention effectively reduces the parasitic effects and improves the performance of the body contact device structure.

### BRIEF DESCRIPTION OF THE DRAWINGS

FIG. 1 illustrates a top view of a body contact device structure according to an embodiment of the present invention;

FIG. 2 illustrates a flowchart of a method for manufacturing a body contact device structure according to an embodiment of the present invention;

FIGS. 3-6 illustrate the top view of the body contact device structure in each manufacturing phase according to the embodiments of the present invention;

FIGS. 3A-6A illustrate the AA′ direction view of the body contact device structure in each manufacturing phase according to the embodiments of the present invention;

FIGS. 3B-6B illustrate the BB′ direction view of the body contact device structure in each manufacturing phase according to the embodiments of the present invention;

FIGS. 4C-6C illustrate the CC′ direction view of the body contact device structure in each manufacturing phase according to the embodiments of the present invention;

FIG. 7 illustrates a top view of a T-type gate structure; and

FIG. 8 illustrates the BB′ direction view of the T-type gate structure in FIG. 7.

### DETAILED DESCRIPTION OF THE EMBODIMENTS

The present invention generally relates to a semiconductor device and a method for manufacturing the same, and particularly, to a body contact device structure based on gate replacement process and a method for manufacturing the same. The following disclosure provides several different embodiments or examples to implement different structures of the present invention. In order to simplify the disclosure of the present invention, the components and arrangements of specific examples are described in the following text. Of course, they are just exemplary, and do not intend to limit the present invention. In addition, reference numbers and/or letters can be repeatedly used in different examples of the present invention for the purposes of simplification and clearness, without indicating the relationships between the discussed embodiments and/or arrangements. Further, the present invention provides examples of various specific processes and materials, but a person skilled in the art can realize the availability of other processes and/or usage of other materials. Moreover, a structure described as follows in which a first feature is “on” a second feature, may include an embodiment where the first and second features are formed to directly contact with each other, or an embodiment where another feature is formed between the first and second features so that the first and second features may not directly contact with each other.

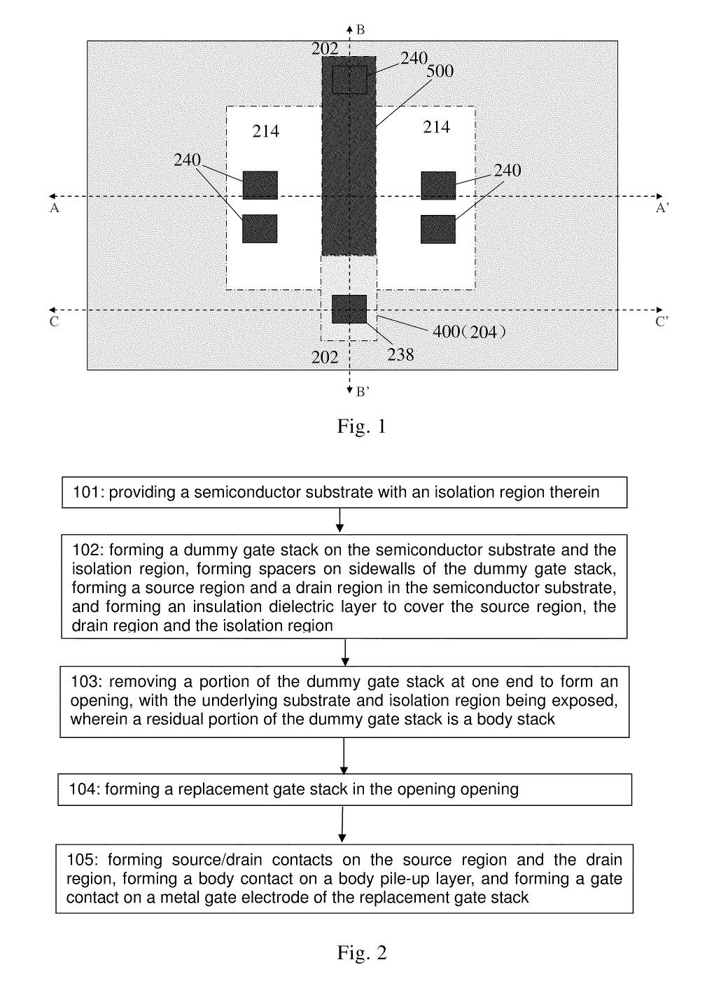

Referring to FIG. 1, FIG. 1 illustrates a body contact device structure according to an embodiment of the present invention. The device structure is formed based on the gate-last process. A replacement gate stack 500 and a body stack 400 are formed on an isolation region 202 and a semiconductor substrate 200 between a source region 214 and a drain region 214. A body pile-up layer 204 of the body stack 400 is directly formed on the substrate 200 and the isolation region 202, and a body contact 238 is formed on the body pile-up layer 204. This device structure effectively reduces the parasitic effects and the device area.

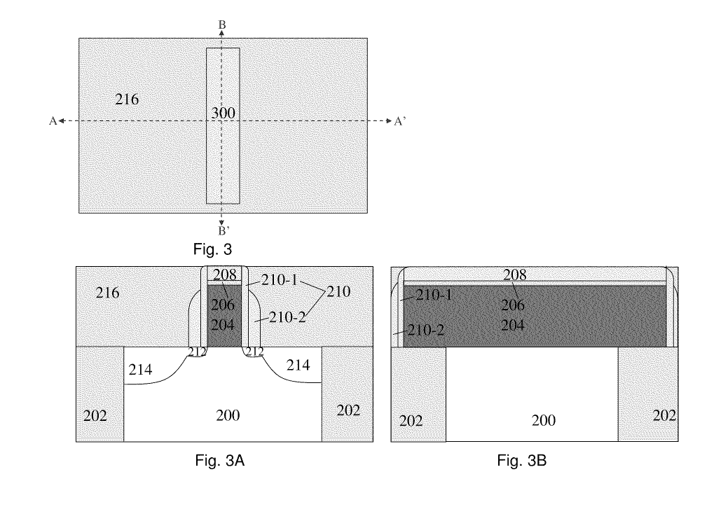

Referring to FIG. 2, FIG. 2 illustrates a method for manufacturing a body contact device structure according to an embodiment of the present invention, and the method for manufacturing the device structure will be detailedly described as follows. In step 101, a semiconductor substrate 200 with an isolation region 202 is provided, as illustrated in FIG. 3A. In this embodiment, the substrate 200 includes a silicon substrate (e.g., wafer) with a crystal structure, and may also include other basic semiconductors or compound semiconductors, such as Ge, GeSi, GaAs, InP, SiC or diamond. According to the known design requirement in the prior art (e.g., p-type substrate or n-type substrate), the substrate 200 may include various doping arrangements. In addition, the substrate 200 may optionally include an epitaxial layer, which may be changed by a stress to enhance its performance, and may include an SOI structure. The isolation region 202 may include SiO₂ or other materials capable of separating the active region of the device.

In step 102, a dummy gate stack 300 is formed on the semiconductor substrate 200 and the isolation region 202; spacers 210 are formed on sidewalls of the dummy gate stack 300; a source region 214 and a drain region 214 are formed in the semiconductor substrate; and an insulation dielectric layer 216 is formed to cover the source region 214, the drain region 214 and the isolation region 202, as illustrated in FIG. 3 (top view), FIG. 3A (AA′ direction view) and FIG. 3B (BB′ direction view). The device structure as illustrated in FIG. 3 can be formed through conventional processing steps, materials and equipments, which is obvious for a person skilled in the art.

The dummy gate stack 300 may be formed by depositing a body pile-up layer 204, a first oxide cap layer 206 and a second nitride cap layer 208 sequentially on the substrate 200 and the isolation region 202, and then patterning the body pile-up layer 204, the first oxide cap layer 206 and the second nitride cap layer 208 by using a dry or wet etching technology. The body pile-up layer 204 may be formed with a material of semiconductor or semiconductor compound different from that of the substrate 200, such as Ge, GeSi, GaAs, InP, SiC, polycrystalline silicon or diamond. The first oxide cap layer 206 may be formed with an oxide material, such as SiO₂. The second nitride cap layer 208 may be formed with a nitride material, such as SiN.

The spacers 210 may be formed of SiN, SiO₂, SiON, SiC, silica glass doped with fluoride, low k dielectric material, any combination thereof, and/or other appropriate materials. The spacers 210 may have a multi-layer structure. The spacers 210 may be formed by depositing appropriate dielectric materials via a method of atomic deposition, plasma enhanced chemical vapor deposition (PECVD) or any other appropriate method. In this embodiment, the spacers are a two-layer structure, including first spacers 210-1 and second spacers 210-2, as illustrated in FIG. 3A.

After the first spacers 210-1 are formed, source/drain (S/D) shallow junctions 212 are formed in the semiconductor substrate 200. After the second spacers 210-2 are formed, the source region 214 and the drain region 214 are formed in the semiconductor substrate 200. The S/D shallow junctions 212, the source region 214 and the drain region 214 may be formed by implanting p-type dopant, n-type dopant or impurity into the substrate 200 according to the required transistor structure, and may be formed by a method including photo-etching, ion implantation, diffusion and/or other appropriate process. The formation of the S/D shallow junctions 212 includes S/D extension and/or halo implantation.

The insulation dielectric layer 216 may be formed by depositing (e.g., via PECVD) an insulation dielectric layer 216 on the device and then planarizing the insulation dielectric layer 216. For example, the insulation dielectric layer 216 on the dummy gate stack 300 may be removed through a chemical mechanical polishing (CMP) method, and the second nitride cap layer 208 is taken as a stop layer to form the structure as illustrated in FIG. 3A. The insulation dielectric layer 216 may be, but not limited to, for example undoped SiO₂, doped SiO₂ (e.g., borosilicate glass, boron-phosphorosilicate glass), etc.

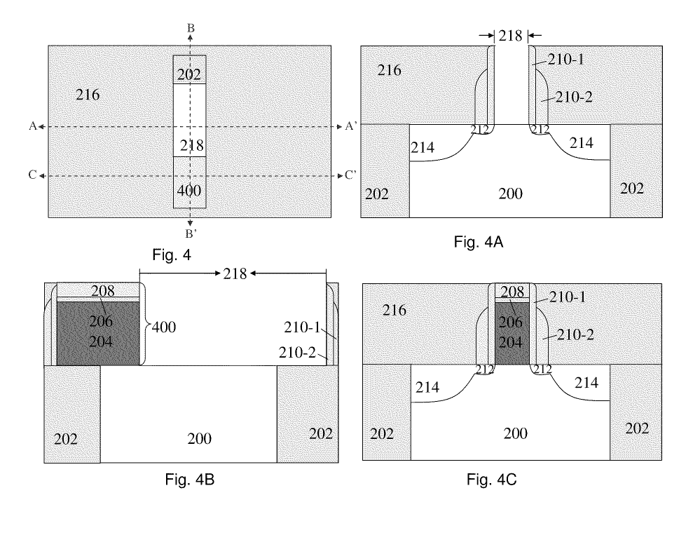

In step 103, a portion of the dummy gate stack 300 at one end is removed to expose the substrate 200 and the isolation region 202, so as to form an opening 218, and the residual portion of the dummy gate stack 300 is a body stack 400, as illustrated in FIG. 4 (top view), FIG. 4A (AA′ direction view) and FIG. 4B (BB′ direction view). One end of the dummy gate stack 300 is masked. Through a method of RIE, the first oxide cap layer 206, the body pile-up layer 204 and the substrate 200 are respectively taken as a stop layer to sequentially remove the second nitride cap layer 208, the first oxide cap layer 206 and the body pile-up layer 204 at the unmasked end of the dummy gate stack 300, so as to form an opening 218. Then the mask is removed, and a residual portion of the dummy gate stack 300 is the body stack 400. The body stack 400 includes the body pile-up layer 204, the first oxide cap layer 206 and the second nitride cap layer 208, as illustrated in FIG. 4B (BB′ direction view) and FIG. 4C (CC′ direction view).

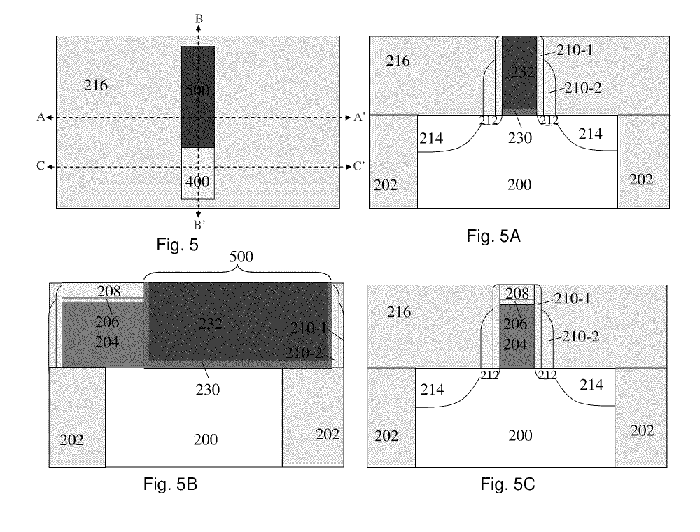

In step 104, a replacement gate stack 500 including a gate dielectric layer 230 and a gate electrode 232 is formed in the opening 218, as illustrated in FIG. 5 (top view), FIG. 5A (AA′ direction view) and FIG. 5B (BB′ direction view). Firstly, the gate dielectric layer 230 and the gate electrode 232 are sequentially deposited on the device. The gate dielectric layer 230 may include, but not limited to, a high k dielectric material (e.g., a material having a higher dielectric constant compared with silicon oxide) including for example hafnium-based materials, such as HfO₂, HfSiO, HfSiON, HfTaO, HfTiO, HfZrO, any combination thereof, and/or other appropriate materials. The gate electrode 232 may be a one-layer or multi-layer structure, and may be, but not limited to, formed by depositing one or more elements selected from the group consisting of TaN, Ta₂C, HfN, HfC, TiC, TiN, TiAl, MoN, MoC, TaTbN, TaErN, TaYbN, TaSiN, TaAlN, TiAlN, TaHfN, TiHfN, HfSiN, MoSiN, MoAlN, Mo, Ru, RuO₂, RuTaₓ, NiTaₓ, polycrystalline silicon, metal silicide and any combination thereof. The gate dielectric layer 230 and the gate electrode 232 may be deposited through a conventional depositing process, such as sputtering, PLD, MOCVD, ALD, PEALD or other appropriate method. Next, through a CMP method, the second nitride cap layer 208 is taken as a stop layer to remove the gate dielectric layer 230 and the gate electrode 232 on the body stack 400 and the insulation dielectric layer 216, so as to form in the opening 218 the replacement gate stack 500 including the gate dielectric layer 230 and the gate electrode 232, as illustrated in FIG. 5A (AA′ direction view) and FIG. 5B (BB′ direction view). In this step, the body stack 400 does not change, as illustrated in FIG. 5C (CC′ direction view).

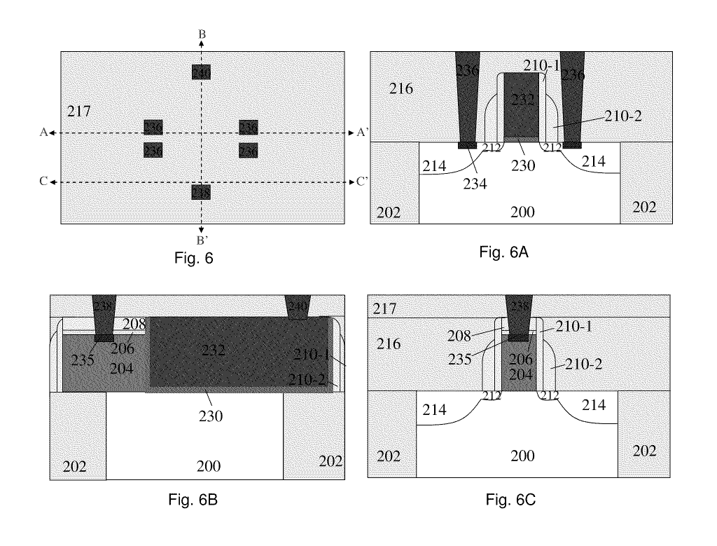

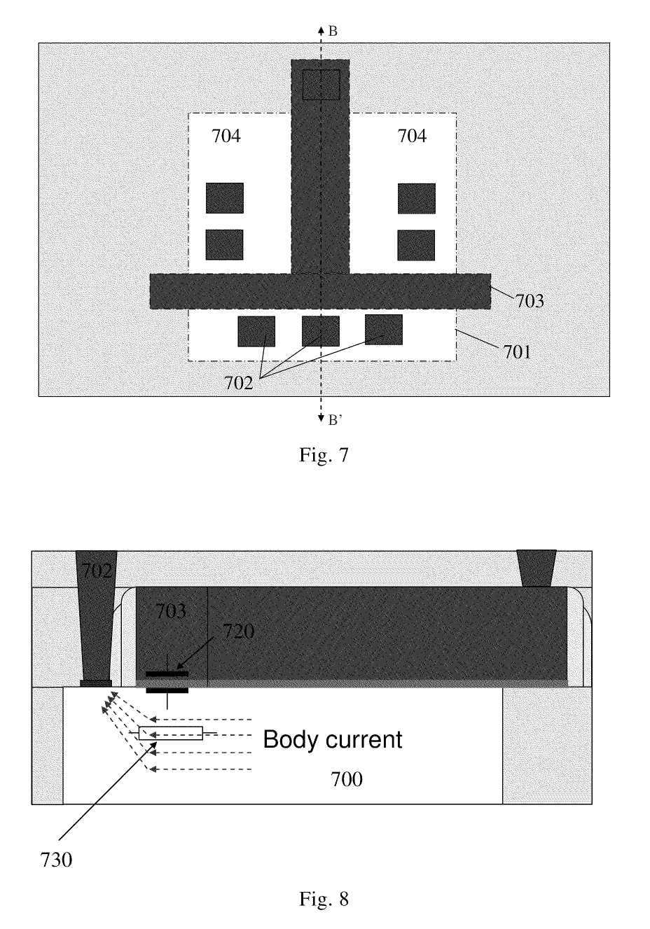

Particularly, after the replacement gate stack 500 is formed, source/drain metal silicide layers 234 are formed on the semiconductor substrate 200 within the source region 214 and the drain region 214, and a body extraction metal silicide layer 235 is formed on the body pile-up layer 204, as illustrated in FIG. 6A (AA′ direction view), FIG. 6B (BB′ direction view) and FIG. 6C (CC′ direction view). Firstly, a second layer of dielectric layer 217 is formed on the insulation dielectric layer 216, and the second layer of dielectric layer 217 may be, but not limited to, undoped SiO₂, doped SiO₂ (e.g., borosilicate glass, boron-phosphorosilicate glass), etc. After that, a selective etching is carried out to form contact holes on the source region 214, the drain region 214, the body pile-up layer 204, and the gate electrode 232 respectively. Then a metal silicification is carried out to form the source/drain metal silicide layers 234 and the body metal silicide layer 235. A material for the metal silicification may be for example Co, Ni, Mo, Pt, W, etc.

In step 105, source/drain contacts 236 are formed on the source region 214 and the drain region 214, a body contact 238 is formed on the body pile-up layer 204, and a gate contact 240 is formed on the gate electrode 232 of the replacement gate stack 500, as illustrated in FIG. 6 (top view), FIG. 6A (AA′ direction view), FIG. 6B (BB′ direction view) and FIG. 6C (CC′ direction view). A contact metal material such as W is deposited on the device to fill up the contact holes, so as to form the source/drain contacts 236, the body contact 238 and the gate contact 240.

The body contact device structure based on the gate-last process and the method of manufacture are described as above. Through the present invention, the body pile-up layer is directly formed on the substrate, and the body contact is formed on the body pile-up layer. This structure decreases the device area, and can effectively reduces the parasitic effects of the T-type and H-type gate structures, so as to improve the performance of the body contact device structure.

Although the exemplary embodiments and the advantages have been detailedly described herein, it shall be appreciated that various changes, substitutions and modifications may be made to these embodiments without deviating from the spirit of the present invention and the protection scopes defined by the accompanied claims. With respect to other examples, it should be easily understood for a person skilled in the art that the sequence of the processing steps may be changed while maintaining the protection scope of the present invention.

Furthermore, the application scope of the present invention is not limited to the processes, structures, manufacturing, compositions, means, methods and steps of the specific embodiments as described in the specification. According to the disclosure of the present invention, a person skilled in the art will easily understood that, when the processes, structures, manufacturing, compositions, means, methods and steps currently existing or to be developed in future are adopted to perform functions substantially the same as corresponding embodiments described in the present invention, or achieve substantially the same effects, a person skilled in the art can make applications of them according to the present invention. Therefore, the attached claims of the present invention intend to include the processes, structures, manufacturing, compositions, means, methods and steps within its protection scope.

What is claimed is:

1. A method for manufacturing a body contact device structure, comprising:
A. providing a semiconductor substrate with an isolation region therein;
B. forming a dummy gate stack on the semiconductor substrate and the isolation region, forming spacers on sidewalls of the dummy gate stack, forming a source region and a drain region in the semiconductor substrate, and forming an insulation dielectric layer to cover the source region, the drain region and the isolation region;
C. removing a portion of the dummy gate stack at one end to form an opening, with the underlying substrate and the isolation region being exposed, wherein a residual portion of the dummy gate stack is a body stack comprising a body pile-up layer that directly contacts the substrate;
D. forming a replacement gate stack, comprising a gate dielectric layer and a gate electrode, in the opening; and
E. forming source/drain contacts on the source region and the drain region, forming a body contact on the body pile-up layer of the body stack, and forming a gate contact on the gate electrode of the replacement gate stack.

2. The method according to claim 1, wherein the body pile-up layer is formed of a material of semiconductor or semiconductor compound different from that of the substrate.

3. The method according to claim 2, wherein the material of semiconductor or semiconductor compound comprises Ge, GeSi, GaAs, InP, SiC, polycrystalline silicon and diamond.

4. The method according to claim 1, wherein the body stack further comprises a first oxide cap layer and a second nitride cap layer.

5. The method according to claim 1, further comprising the following step between steps D and E: forming source/drain metal silicide layers on the semiconductor substrate within the source region and the drain region, and forming a metal silicide layer on the body pile-up layer.

6. A body contact device structure, comprising:
a semiconductor substrate with an isolation region therein;
a source region and a drain region formed on the semiconductor substrate;
a body stack and a replacement gate stack formed on the isolation region and the semiconductor substrate between the source region and the drain region respectively, to wherein the body stack comprises a body pile-up layer, and the replacement gate stack comprises a gate dielectric layer and a gate electrode;
spacers formed on sidewalls of the body stack and the replacement gate stack; and
source/drain contacts formed on the source region and the drain region, a body contact on the body pile-up layer, and a gate contact on the gate electrode.

7. The body contact device structure according to claim 6, wherein the body pile-up layer is formed of a material of semiconductor or semiconductor compound different from that of the substrate.

8. The body contact device structure according to claim 7, wherein the material of semiconductor or semiconductor compound comprises Ge, GeSi, GaAs, InP, SiC, polycrystalline silicon and diamond.

9. The body contact device structure according to claim 6, further comprising source/drain metal silicide layers between the substrate within the source region and the drain region and the source/drain contacts.

10. The body contact device structure according to claim 6, further comprising a metal silicide layer between the body contact and the body pile-up layer.

11. The body contact device structure according to claim 6, wherein the body stack further comprises a first oxide cap layer and a second nitride cap layer.
